(19) United States
(12) Patent Application Publication
(10) Pub. No.: US 2025/0359362 A1
(43) Pub. Date: Nov. 20, 2025

(54) UNIT PIXEL WITH MULTIPLE PHOTOELECTRIC CONVERSION ELEMENTS

(71) Applicant: Himax Imaging Limited, Tainan City (TW)

(72) Inventor: Hsin-Hung Shen, Tainan City (TW)

(73) Assignee: Himax Imaging Limited, Tainan City (TW)

(21) Appl. No.: 18/669,460

(22) Filed: May 20, 2024

(51) Int. Cl. H01L 27/146; H04N 25/57; H04N 25/77

(52) U.S. Cl. CPC H10F 39/8023; H04N 25/57; H04N 25/77; H10F 39/182; H10F 39/8053; H10F 39/8063; H10F 39/807

(57) ABSTRACT

A unit pixel includes a large photoelectric conversion region and a small photoelectric conversion region. The large photoelectric conversion region has a hollow columnar shape, and is configured to convert incident light into a first charge. The small photoelectric conversion region has a columnar shape. The small photoelectric conversion region is surrounded by the large photoelectric conversion region and configured to convert incident light into a second charge.

### BACKGROUND OF THE INVENTION

### 1. Field of the Invention

The present invention relates generally to imaging devices, and more particularly, to imaging sensors having unit pixels with multiple photoelectric conversion elements.

### 2. Description of the Prior Art

Recently, complementary metal-oxide-semiconductor (CMOS) transistor image sensors (CIS), have found extensive applications across a wide array of sectors including consumer electronics, industrial automation, medical imaging, security and surveillance, automotive technologies, and aerospace engineering. As application scenarios become increasingly complex, the demands on CIS technology have escalated, necessitating advancements in sensor capabilities to meet the rigorous requirements of high resolution, fast readout, low light sensitivity and rapid image processing in diverse and challenging environments.

In certain scenarios, lighting conditions are complex, resulting in a significant disparity between the luminance of bright and dark areas. This vast luminance range exceeds the dynamic range of conventional CIS, leading to images where details in either the highlights or shadows (or both) are lost. Consequently, there is an increasing demand for high dynamic range (HDR) imaging technology. HDR imaging addresses this challenge by combining multiple exposures to capture a wider range of luminance levels. Typically, HDR imaging generates two separate images. One image is generated using a prolonged exposure period to capture enough photons for the dark and shadowy areas. The other image uses a short exposure period to capture photons for the brightly lit areas. These images are then merged using algorithms, combining the best-exposed parts of each image into a single HDR image with enhanced details in both the darkest and brightest areas of the scene. However, multiple exposures required for HDR imaging can lead to artifacts in the HDR image.

Therefore, HDR imaging can be achieved by splitting a photodiode within a unit pixel of the CIS into two distinct photodiodes: one small and one large. This configuration allows both photodiodes in the unit pixel to be exposed simultaneously during a single exposure period, thereby mitigating the occurrence of artifacts. However, the structure of having both large and small photodiodes within a same unit pixel presents several challenges. Firstly, the small photodiode is typically positioned at a corner of the unit pixel, leading to inconsistencies in the optical centers between the large and small photodiodes within the same pixel. Moreover, the small photodiode is more susceptible to inference from the larger photodiodes of adjacent unit pixels. Additionally, both the large and small photodiodes within the same unit pixel require their own dedicated color filters and micro lenses, which increase the complexity and cost of fabrication. Specifically, the small photodiodes necessitate smaller color filters and micro lenses, presenting greater manufacturing challenges.

In view of this, there is a need for an innovative design of the large and small photodiode configuration to overcome the aforementioned problems.

### SUMMARY OF THE INVENTION

With this in mind, it is one object of the present invention to provide innovative structure of a unit pixel having multiple photoelectric conversion elements/regions. In embodiments of the present invention, a smaller photoelectric conversion element/region of a unit pixel is surrounded by a larger photoelectric conversion element/region thereof. This ensures consistencies in the optical centers between the larger and smaller photoelectric conversion elements/regions within the same pixel, reducing occurrence of artifacts. Such structure allows inferences from the large photoelectric conversion of adjacent unit pixels to be blocked and therefore the image quality can be improved. Moreover, such structure also allows the larger and smaller photoelectric conversion elements/regions to share a same micro-lens unit and a same color filter (unit), which significantly reduce the complexity and cost of fabrication.

According to one embodiment, a unit pixel is provided. The unit pixel comprises a large photoelectric conversion region and a small photoelectric conversion region. The large photoelectric conversion region has a hollow columnar shape, and is configured to convert incident light into a first charge. The small photoelectric conversion region has a columnar shape. The small photoelectric conversion region is surrounded by the large photoelectric conversion region and configured to convert incident light into a second charge.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram illustrating an image sensor according to one embodiment of the present invention.

FIG. 2A is a circuit diagram illustrating a unit pixel of an image sensor according to a first embodiment of the present invention.

FIG. 2B is a diagram illustrating a top view of semiconductor structure of a unit pixel according to a first embodiment of the present invention.

FIG. 2C is a diagram illustrating a cross-sectional view of semiconductor structure of a unit pixel according to a first embodiment of the present invention.

FIG. 2D is a circuit diagram illustrating a unit pixel with dual gain conversion feature according to a first embodiment of the present invention.

FIG. 3A is a circuit diagram illustrating a unit pixel of an image sensor according to a second embodiment of the present invention.

FIG. 3B is a diagram illustrating a top view of semiconductor structure of a unit pixel according to a second embodiment of the present invention.

FIG. 3C is a diagram illustrating a cross-sectional view of semiconductor structure of a unit pixel according to a second embodiment of the present invention.

FIG. 3D is a circuit diagram illustrating a unit pixel with dual gain conversion feature according to a second embodiment of the present invention.

### DETAILED DESCRIPTION

In the following description, numerous specific details are described to provide a thorough understanding of embodiments of the invention. One skilled in the relevant art will recognize, however, that the invention can be practice without one or more of the specific details, or with other methods, components, materials, etc. In other instances, well-known structures, materials or operations are not shown or described in details but are nonetheless encompassed within the scope of the invention.

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments. Directional terminology such as “top”, “bottom”, “under” is used with reference to the orientation of the figure(s) being described.

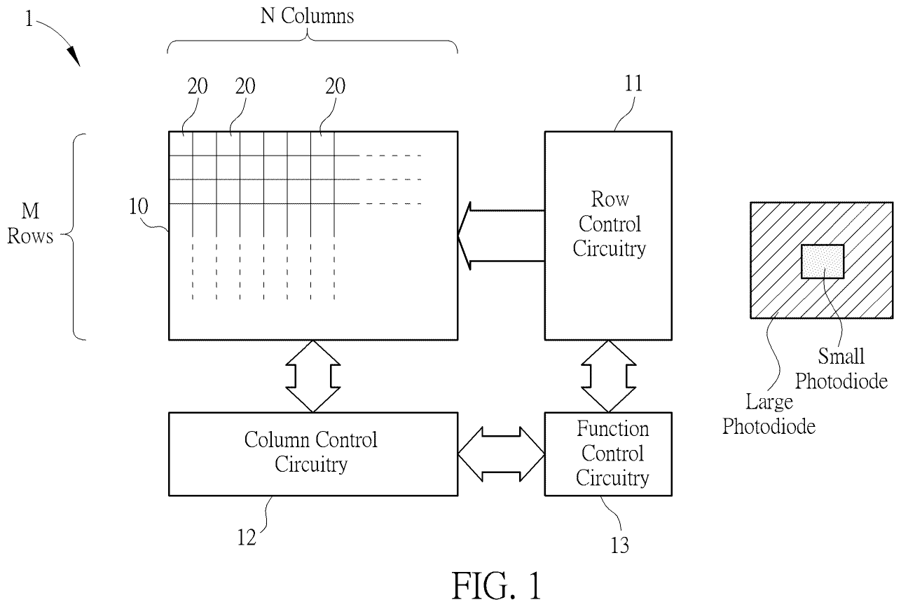

Please refer to FIG. 1, which illustrates an image sensor 1 according to one embodiment of the present invention. Preferably, the image sensor 1 is a complementary metal-oxide-semiconductor (CMOS) image sensor and may be implemented as a frontside illuminated image sensor or a backside illuminated image sensor. The image sensor 1 includes a pixel array 10 containing a plurality of unit pixels 20 that may be arranged two-dimensionally, for example, may be arranged in the form of a matrix consisting of M rows and N columns. The image sensor 1 further includes a row control circuitry 11, and a column control circuitry 12 and a function control circuitry 13.

The row control circuitry 11 may receive row addresses from the function control circuitry 13 and supply corresponding row control signals (e.g., reset, row-selecting, charge transfer, dual conversion gain control and readout control signals) to the unit pixels 20. The column control circuitry 12 may receive image signals from the pixel array 10. The column control circuitry 12 may include (but is not shown): sample-and-hold circuitry for sampling and temporarily storing image signals read out from the pixel array 10, amplifier circuitry for amplifying the image signals, analog-to-digital conversion circuitry for converting the image signals into digital values, bias circuitry for charging columns of the pixel array 10 and/or other circuitry that is coupled to one or more columns of unit pixels 20 in the pixel array 10 for operating the unit pixels 20 and for reading out image signals from unit pixels 20. The column control circuitry 12 may supply digital pixel data to the function control circuitry 13 for further processing.

In addition, each of the unit pixels 20 comprises a (relatively) large photoelectric conversion region and a (relatively) small photoelectric conversion region for implementing high dynamic range (HDR) imaging, allowing the image sensor 1 to capture a wider range of luminance levels within a single frame, thereby to record details in both bright and dark areas of the scene. Specifically, each of the large photoelectric conversion region and the small photoelectric conversion region absorbs incident light and accumulate photo-generated charges based on the intensity of incident light. According to various embodiments, each of the large photoelectric conversion region and the small photoelectric conversion region may be implemented as a photodiode, a phototransistor, a photo-gate, a pinned-photodiode, or a combination thereof.

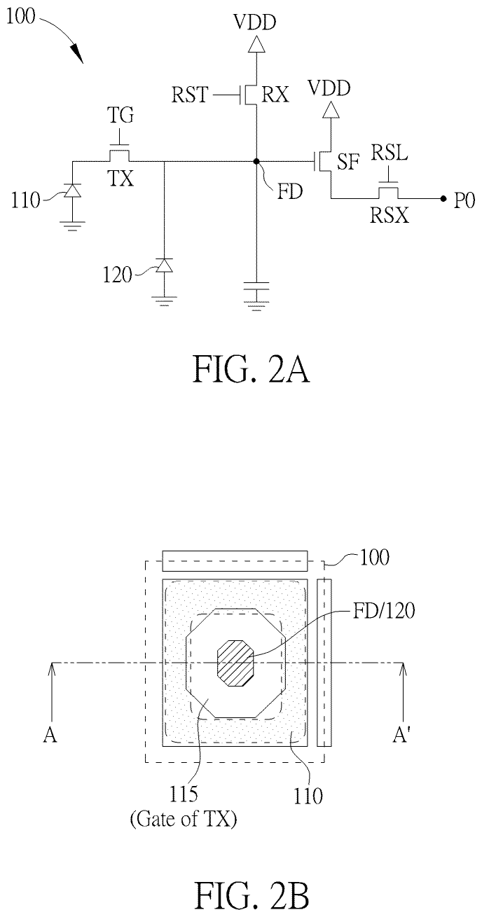

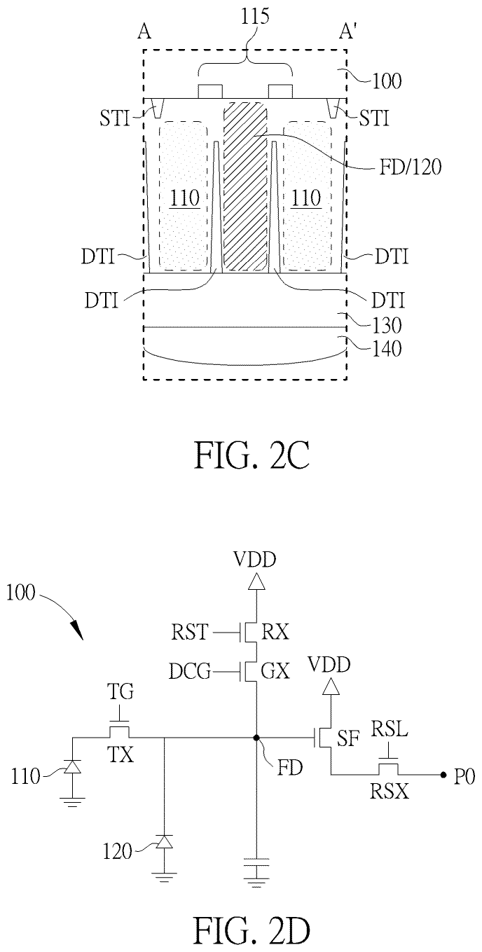

Please refer to FIG. 2A-2D, which are diagrams illustrating structure of a single unit pixel according to one embodiment of the present invention. As illustrated by FIG. 2A, a unit pixel 100 comprises a large photodiode 110 (implemented by a large photoelectric conversion region) and a small photodiode 120 (implemented by a small photoelectric conversion region) for convert photons into charges. In addition, the unit pixel 100 also includes a transfer transistor TX, a reset transistor RX, a source follower transistor SF, a row select transistor RSX, a floating diffusion node FD and a capacitor (which may represent an additional physical capacitor coupled to the floating diffusion node FD or may simply represent the inherent capacitance associated with the floating diffusion node FD). In this embodiment, the small photodiode 120 is formed by the floating diffusion node FD.

In addition, a control signal TG is utilized to control the conductivity of the transfer transistor TX, a control signal RST is utilized to control the conductivity of the reset transistor RX, and a control signal RSL is utilized to control the conductivity of the row select transistor RSX. A voltage at the floating diffusion node FD controls the conductivity of the source follower transistor SF. The output of the source follow transistor SF is presented at node PO when the row select transistor RSX is conducting. The state of the transfer transistor TX determines whether the floating diffusion node FD is coupled to the large photodiode 110 for receiving charge generated by the large photodiode 110 following an exposure period. The state of the reset transistors RX determines whether the floating diffusion node FD is coupled to a pixel power VDD during a reset period.

The unit pixel 100 is operated as follows. First, the small photodiode 120 is exposed to incident light and accumulates charges during an exposure period. After the exposure period, charge flows to the small photodiode 120 and diminishes the voltage at the floating diffusion node FD. Then, the control signal RSL is asserted to cause the row select transistor RSX to conduct and the control signal TG is not asserted. Accordingly, a sensed signal Vsig_S regarding the small photodiode 120 can be read out from the node PO (through a readout circuit in the column control circuitry 12 of FIG. 1). Then, the control signal RST is asserted while the control signal TG is not asserted, which couples the floating diffusion node FD to the pixel power VDD and resets the voltage at the floating diffusion node FD to the pixel power VDD. Accordingly, a reference signal Vrst regarding both the large photodiode 110 and the small photodiode 120 can be read out from the node PO. Hence, a pixel output Voutput_S of the small photodiode 120 can be determined by Voutput_S=Vrst−Vsig_S. After obtaining the pixel output Voutput_S of the small photodiode 120, the large photodiode 110 is exposed to incident light and accumulates charges during the exposure period. After the exposure period, the control signal TG is asserted to conduct the transfer transistor SX, which couples the floating diffusion node FD to the large photodiode 110. Charge flows through the transfer transistor TX and diminishes the voltage at the floating diffusion node FD. Accordingly, a sensed signal Vsig_L regarding the large photodiode 110 can be read out from the node PO. Hence, a pixel output Voutput_L of the large photodiode 210 can be determined by Voutput_L=Vrst−Vsig_L.

Please refer to FIG. 2B in conjunction with FIG. 2C, which illustrate a top view and a cross-sectional view of semiconductor structure of the unit pixel 100 according to one embodiment of the present invention. As illustrated, the large photodiode 110 has a hollow columnar shape, while the small photodiode 120 has a columnar shape and is surrounded by the large photodiode 110, both of which are disposed in a semiconductor layer (e.g., a substrate). A gate region 115 (which serves as a gate terminal of the transfer transistor TX) has a ring shape and is disposed over the large photodiode 110 and the small photodiode 120 and configured to provide a channel for transferring photo-generated charges to the floating diffusion node FD. In this embodiment, the small photodiode 120 is formed by the floating diffusion node FD (i.e., an implant region of the semiconductor layer) and is positioned beneath an aperture of the gate region 115. In addition, multiple shallow trench isolation (STI) regions and deep trench isolation (DTI) regions, which may have hollow columnar shapes, are disposed in the semiconductor layer to reduce optical and electrical interference between adjacent photodiodes and adjacent unit pixels 100. In one embodiment, a DTI region having a hollow columnar shape is disposed between the large photodiode 110 and the small photodiode 120. Moreover, the large photodiode 110 and the small photodiode 120 share a same color filter (unit) 130 (i.e., corresponding to a same color) and a same micro lens (unit) 140, wherein the color filter (unit) 130 and the micro lens (unit) 140 are disposed on a light receiving side that is opposite to the side the gate region 115 is disposed, i.e., the unit pixel 100 is backside illuminated sensing pixel.

FIG. 2D is a circuit diagram of a unit pixel according to an alternative implementation. In this implementation, the unit pixel 100 includes a dual gain conversion feature, which is realized by a gain control transistor DX. Typically, the gain control transistor DX is controlled by a control signal DCG. According to the conductivity of the control transistor DX is, a capacitance provided by the gain control transistor DX will be either connected or disconnected to the floating diffusion node FD, thereby to provide a high conversion gain mode or a low conversion gain mode.

The unit pixel 100 with dual gain conversion feature is operated as follows. First, the control signal DCG is asserted to conduct the gain control transistor DX, thereby entering a low conversion gain mode. Then, the small photodiode 120 is exposed during the exposure period. After the exposure period, the control signal RSL is asserted to cause the row select transistor RSX to conduct and the control signal TG is not asserted. Accordingly, a sensed signal regarding the small photodiode 120 with the low conversion gain can be read out from the node PO. Then, the control signal RST is asserted while the control signal TG is not asserted, which couples the floating diffusion node FD to the pixel power VDD and resets the voltage at the floating diffusion node FD to the pixel power VDD. Accordingly, a reference signal regarding both the large photodiode 110 and the small photodiode 120 with the low conversion gain can be read out from the node PO.

Then, the control signal DCG is not asserted to cutoff the gain control transistor DX, thereby entering a high conversion gain mode. With the control signal RST being asserted and the control signal TG not being asserted, the floating diffusion node FD remains connected to the pixel power VDD. Accordingly, a reference signal regarding the large photodiode 110 with the high conversion gain can be read out from the node PO. After that, the control signal RST is not asserted, the large photodiode 110 is exposed to incident light. After the exposure period, the control signal TG is asserted to conduct the transfer transistor SX, which couples the floating diffusion node FD to the large photodiode 110. Charge flows through the transfer transistor TX and diminishes the voltage at the floating diffusion node FD. Accordingly, a sensed signal regarding the large photodiode 110 with the high conversion gain can be read out from the node PO.

Last, the control signal DCG is again asserted to enter the low conversion gain mode. With the control signal TG being asserted, the floating diffusion node FD remains connected to the large photodiode 110. Accordingly, a sensed signal regarding the large photodiode 110 with the low conversion gain can be read out from the node PO.

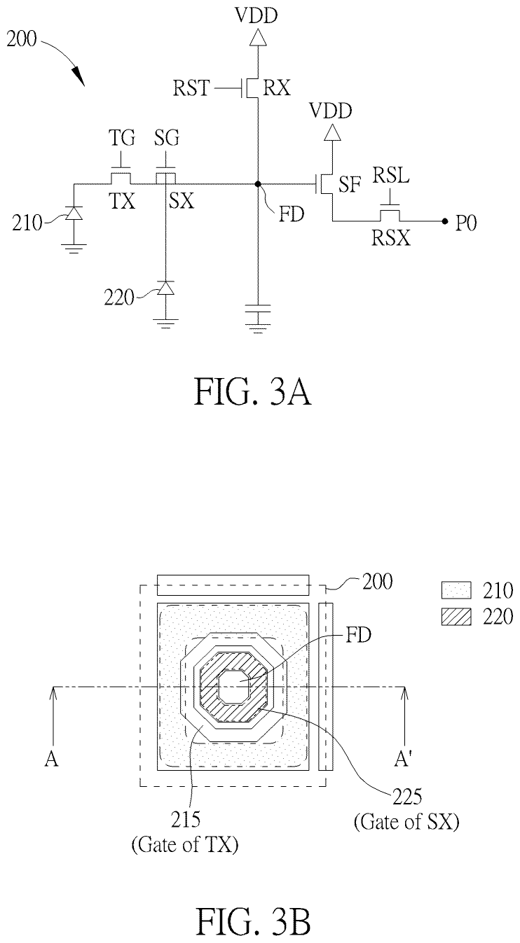

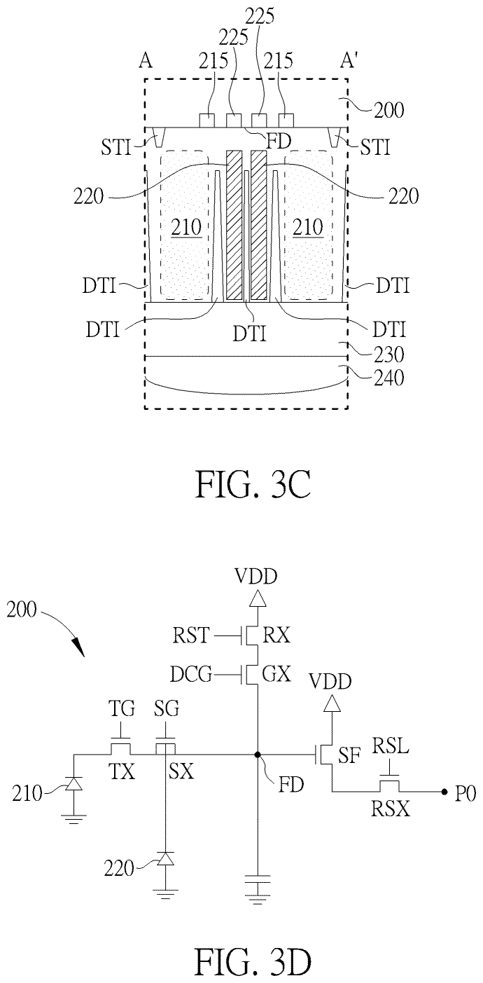

Please refer to FIG. 3A-3D, which are diagrams illustrating structure of a single unit pixel according to one embodiment of the present invention. As illustrated, a unit pixel 200 comprises a large photodiode 210 (implemented by a large photoelectric conversion region) and a small photodiode 220 (implemented by a small photoelectric conversion region) for convert photons into charges. In addition, the unit pixel 200 also includes: a transfer transistor TX controlled by a control signal TG, a storage transistor SX controlled by a control signal SG, a reset transistor RX controlled by a control signal RST, a source follower transistor SF, a row select transistor RSX controlled by a control signal RSL, a floating diffusion node FD, and a capacitor (which may represent an additional physical capacitor coupled to the floating diffusion node FD or may simply represent the inherent capacitance associated with the floating diffusion node FD). In this embodiment, the small photodiode 220 is formed by a body/bulk of the storage transistor SX.

A voltage at the floating diffusion node FD controls the conductivity of the source follower transistor SF. The output of the source follow transistor SF is presented at node PO when the row select transistor RSX is conducting. The states of the transfer transistor TX and the storage transistor SX determine whether the floating diffusion node FD is coupled to the large photodiode 210 for receiving charge generated by the large photodiode 210 following an exposure period. In addition, the state of the storage transistor SX determines whether the floating diffusion node FD is coupled to the small photodiode 220 for receiving charge generated by the small photodiode 220 following an exposure period. The state of the reset transistors RX determines whether the floating diffusion node FD is coupled to a pixel power VDD during a reset period.

The unit pixel 200 is operated as follows. First, the control signal RSL is asserted to cause the row select transistor RSX to conduct. Then, the control signal RST is asserted while the control signal TG for controlling the transfer transistor TX and the control signal SG for controlling the storage transistor TX are both not asserted, which only couples the floating diffusion node FD to the pixel power VDD and resets the voltage at the floating diffusion node FD to the pixel power VDD. Accordingly, a reference signal Vrst_S regarding the small photodiode 220 can be read out from the node PO. After the reference signal Vrst_S has been read, the control signal RST is not asserted. Then, the small photodiode 220 is exposed to incident light and accumulates charges during the exposure period. After the exposure period, the control signal SG is asserted to conduct the storage transistor SX, which couples the floating diffusion node FD to the small photodiode 220. Charge flows through the storage transistor SX and diminishes the voltage at the floating diffusion node FD. Accordingly, a sensed signal Vsig_S regarding the small photodiode 220 can be read out from the node PO. Hence, a pixel output Voutput_S of the small photodiode 220 can be determined by Voutput_S=Vrst_S−Vsig_S.

After obtaining the pixel output Voutput_S of the small photodiode 220, the control signal RST is asserted again while the control signal TG for controlling the transfer transistor TX and the control signal SG for controlling the storage transistor TX are both not asserted, which only couples the floating diffusion node FD to the pixel power VDD and resets the voltage at the floating diffusion node FD to the pixel power VDD. Accordingly, a reference signal Vrst_L regarding the large photodiode 210 can be read out from the node PO. After the reference signal Vrst_L has been read, the control signal RST is not asserted. Then, the large photodiode 210 is exposed to incident light and accumulates charges during the exposure period. After the exposure period, the control signal SG is asserted to conduct the storage transistor SX and the control signal TG is asserted to conduct the transfer transistor SX, which couples the floating diffusion node FD to the large photodiode 210. Charge flows through the storage transistor SX and the transfer transistor TX and diminishes the voltage at the floating diffusion node FD. Accordingly, a sensed signal Vsig_L regarding the large photodiode 210 can be read out from the node PO. Hence, a pixel output Voutput_L of the large photodiode 210 can be determined by Voutput_L=Vrst_L−Vsig_L.

Please refer to FIG. 3B in conjunction with FIG. 3C, which illustrate a top view and a cross-sectional view of semiconductor structure of the unit pixel 200 according to one embodiment of the present invention. As illustrated, the large photodiode 210 has a larger hollow columnar shape, while the small photodiode 220 has a smaller hollow columnar shape and is surrounded by the large photodiode 210, both of which are disposed in a semiconductor layer (e.g., a substrate). A first gate region 215 (which serves as a gate terminal of the transfer transistor TX) has a larger ring shape and is disposed over the large photodiode 210 and the small photodiode 220. A second gate region 225 (which serves as a gate terminal of the storage transistor SX) has a smaller ring shape and is positioned directly above the small photodiode 220 and positioned within an aperture of the first gate region 215. In this embodiment, the small photodiode 220 is formed by a body/bulk region of the storage transistor SX. A floating diffusion node FD (i.e., an implant region in the semiconductor layer) is positioned beneath an aperture of the second gate region 225. In addition, multiple STI regions and DTI regions, which may have columnar shapes, are disposed in the semiconductor layer to reduce optical and electrical interference between adjacent photodiodes and adjacent unit pixels 200. In one embodiment, a DTI region having a hollow columnar shape is disposed between the large photodiode 210 and the small photodiode 220, and another DTI region having a columnar shape is positioned within an aperture of the small photodiode 220.

Moreover, the large photodiode 210 and the small photodiode 220 share a same color filter (unit) 230 (i.e., corresponding to a same color) and a same micro lens (unit) 240, wherein the color filter (unit) 230 and the micro lens (unit) 240 are disposed on a light receiving side that is opposite to the side the first gate region 215 and the second gate region 225 are disposed, i.e., the unit pixel 200 is backside illuminated sensing pixel.

FIG. 3D is a circuit diagram of a unit pixel according to an alternative implementation. In this implementation, the unit pixel 200 include a dual gain conversion feature, which is realized by a gain control transistor DX that is controlled by a control signal DCG. With the control transistor DX is, the unit pixel 200 is operable between a high conversion gain mode or a low conversion gain mode.

The unit pixel 200 is operated as follows. First, the control signal DCG is asserted to enter a low conversion gain mode. Accordingly, the control signal RSL is asserted to cause the row select transistor RSX to conduct. Then, the control signal RST is asserted while the control signal TG for controlling the transfer transistor TX and the control signal SG for controlling the storage transistor TX are both not asserted, which resets the voltage at the floating diffusion node FD to the pixel power VDD. Accordingly, a reference signal regarding the small photodiode 220 with low conversion gain can be read out from the node PO. After that, the control signal RST is not asserted and the small photodiode 220 is exposed to incident light during the exposure period. After the exposure period, the control signal SG is asserted to conduct the storage transistor SX, which couples the floating diffusion node FD to the small photodiode 220. Accordingly, a sensed signal regarding the small photodiode 220 with low conversion gain can be read out from the node PO. After that, the control signal RST is again asserted while the control signal TG for controlling the transfer transistor TX and the control signal SG for controlling the storage transistor TX are both not asserted, which resets the voltage at the floating diffusion node FD to the pixel power VDD, thereby reading out a reference signal regarding the large photodiode 210 with low conversion gain from the node PO.

Second, the control signal DCG is not asserted to enter a high conversion gain mode. The control signal RST is asserted again while the control signal TG for controlling the transfer transistor TX and the control signal SG for controlling the storage transistor TX are both not asserted, which resets the voltage at the floating, thereby reading out a reference signal regarding the large photodiode 210 with the high conversion gain from the node PO. Then, the large photodiode 210 is exposed to incident light during the exposure period. After the exposure period, the control signal SG and the control signal TG are asserted to couple the floating diffusion node FD to the large photodiode 210, thereby reading out a sensed signal regarding the large photodiode 210 with the high conversion gain from the node PO.

Last, the control signal DCG is again asserted to enter the low conversion gain mode. With the control signal TG and the control signal SG being asserted, the floating diffusion node FD remains connected to the large photodiode 210. Accordingly, a sensed signal regarding the large photodiode 210 with the low conversion gain can be read out from the node PO.

In conclusion, the present invention provides innovative structure of a unit pixel having multiple photoelectric conversion elements/regions. In the structure of the unit pixel of the present invention, the smaller photoelectric conversion element/region of a unit pixel is surrounded by the larger photoelectric conversion element/region thereof, which ensures consistencies in the optical centers between the larger and smaller photoelectric conversion elements/regions within the same unit pixel, reducing occurrence of artifacts. Such structure allows inferences from the large photoelectric conversion of adjacent unit pixels to be blocked and therefore the image quality can be improved. Moreover, the present invention also allows the larger and smaller photoelectric conversion elements/regions to share a same micro-lens unit and a same color filter (unit), which significantly reduce the complexity and cost of fabrication.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A unit pixel, comprising:
a large photoelectric conversion region, having a hollow columnar shape, configured to convert incident light into a first charge; and
a small photoelectric conversion region, having a columnar shape, surrounded by the large photoelectric conversion region, configured to convert incident light into a second charge.

2. The unit pixel of claim 1, wherein the small photoelectric conversion region is formed by a floating diffusion node of the unit pixel.

3. The unit pixel of claim 2, wherein further comprising:
a gate region having a ring shape, disposed over the large photoelectric conversion region and the small photoelectric conversion region, wherein the small photoelectric conversion region is positioned beneath an aperture of the gate region.

4. The unit pixel of claim 2, further comprising:
a shared color filter unit; and
a shared micro lens unit;
wherein the shared color filter unit and the shared micro lens unit are disposed on a light receiving side of the unit pixel that is opposite to a side the gate region is disposed.

5. The unit pixel of claim 2, further comprising:
a deep trench isolation region, having a hollow columnar shape, disposed between the large photoelectric conversion region and the small photoelectric conversion region.

6. The unit pixel of claim 1, wherein further comprising:
a first gate region having a larger ring shape, disposed over the large photoelectric conversion region; and
a second gate region having a smaller ring shape, disposed over the small photoelectric conversion region;
wherein the second gate region is positioned within an aperture of the first gate region.

7. The unit pixel of claim 6, wherein the small photoelectric conversion region has a hollow columnar shape and is formed by a body/bulk region of a transistor whose gate terminal is the second gate region; and the second gate region is positioned directly above the small photoelectric conversion region.

8. The unit pixel of claim 6, wherein a floating diffusion region of the unit pixel and is positioned beneath an aperture of the the second gate region.

9. The unit pixel of claim 6, further comprising:
a first deep trench isolation region, having a hollow columnar shape, disposed between the large photoelectric conversion region and the small photoelectric conversion region; and
a second deep trench isolation region, having a columnar shape, positioned within an aperture of the small photoelectric conversion region.

10. The unit pixel of claim 6, further comprising:
a shared color filter unit; and
a shared micro lens unit;
wherein the shared color filter and the shared micro lens are disposed on a light receiving side of the unit pixel that is opposite to a side that the first gate region and the second gate region are disposed.

11. The unit pixel of claim 1, wherein the large photoelectric conversion region and the small photoelectric conversion region respectively forms a photodiode, a phototransistor, a photo-gate, a pinned-photodiode, or a combination thereof.

12. An image sensor comprising a plurality of unit pixels of claim 1 that are two-dimensionally arranged.
